(19) United States
(12) Patent Application Publication
(10) Pub. No.: US 2023/0317498 A1
(43) Pub. Date: Oct. 5, 2023

(54) LIGHT-EMITTING ELEMENT PANEL

(71) Applicant: AUO Corporation, Hsinchu (TW)

(72) Inventors: Wei-Chieh Chen, Hsinchu (TW); Kuan-Yi Lee, Hsinchu (TW); Chih-Chun Yang, Hsinchu (TW); Chia-Hui Pai, Hsinchu (TW)

(73) Assignee: AUO Corporation, Hsinchu (TW)

(21) Appl. No.: 18/090,462

(22) Filed: Dec. 28, 2022

Related U.S. Application Data
(60) Provisional application No. 63/326,437, filed on Apr. 1, 2022.

(30) Foreign Application Priority Data
Jul. 5, 2022 (TW) 111125211

(51) Int. Cl. H01L 21/683; H01L 33/00; H01L 33/20; H01L 25/075; H01L 33/38

(52) U.S. Cl. CPC H01L 21/6835; H01L 33/0093; H01L 33/20; H01L 25/0753; H01L 33/382; H01L 33/32

(57) ABSTRACT

A light-emitting element panel, including a temporary storage substrate, an auxiliary pattern layer, multiple adhesive patterns, and multiple light-emitting elements, is provided. The auxiliary pattern layer is disposed on the temporary storage substrate and has multiple openings. The adhesive patterns are respectively disposed in the openings of the auxiliary pattern layer. The light-emitting elements are respectively disposed on the adhesive patterns. A reaction rate of the auxiliary pattern layer to a laser is lower than a reaction rate of the adhesive pattern to the laser. Moreover, another light-emitting element panel is also provided.

### CROSS-REFERENCE TO RELATED APPLICATION

This application claims the priority benefit of U.S. Provisional Application No. 63/326,437, filed on Apr. 1, 2022 and Taiwan Application No. 111125211, filed on Jul. 5, 2022. The entirety of each of the above-mentioned patent applications is hereby incorporated by reference herein and made a part of this specification.

### BACKGROUND

### Technical Field

The disclosure relates to a light-emitting element panel.

### Description of Related Art

A light-emitting diode display panel includes a driving backplane and multiple light-emitting diode elements transposed on the driving backplane. Inheriting the characteristics of a light-emitting diode, the light-emitting diode display panel has advantages such as power saving, high efficiency, high brightness, and fast response time. In addition, compared with an organic light-emitting diode display panel, the light-emitting diode display panel also has advantages such as easy color adjustment, long light-emitting life, and no image burn-in. Therefore, the light-emitting diode display panel is regarded as the next generation display technology.

During the manufacturing process of the light-emitting diode display panel, firstly, the light-emitting diode elements on a growth substrate must be transferred to an adhesive layer on a first temporary storage substrate. Next, in a case where the light-emitting diode elements are disposed on the adhesive layer on the first temporary storage substrate, the adhesive layer is etched, so that the adhesive layer on the first temporary storage substrate forms multiple adhesive patterns. The adhesive patterns respectively overlap with the light-emitting diode elements. However, if the etching is incomplete and the adhesive patterns are still partially connected to each other, during the subsequent manufacturing process, when the adhesive patterns and the light-emitting diode elements thereon are redistributed to a second temporary storage substrate, the light-emitting diode elements on the second temporary storage substrate may be easily offset and/or rotated, thereby causing the inability of the light-emitting diode elements on the second temporary storage substrate to be smoothly bonded to the driving backplane. On the other hand, if the adhesive layer is over-etched in order to completely separate the adhesive patterns on the first temporary storage substrate, the light-emitting diode elements on the adhesive layer may be easily damaged.

### SUMMARY

The disclosure provides a light-emitting element panel, which can improve transfer yield.

The disclosure provides another light-emitting element panel, which can improve transfer yield.

A light-emitting element panel according to an embodiment of the disclosure includes a temporary storage substrate, an auxiliary pattern layer, multiple adhesive patterns, and multiple light-emitting elements. The auxiliary pattern layer is disposed on the temporary substrate and has multiple openings. The adhesive patterns are respectively disposed in the openings of the auxiliary pattern layer. The light-emitting elements are respectively disposed on the adhesive patterns. A reaction rate of the auxiliary pattern layer to a laser is lower than a reaction rate of the adhesive pattern to the laser.

A light-emitting element panel according to an embodiment of the disclosure includes a temporary storage substrate, an adhesive layer, multiple light-emitting elements, and multiple adhesive patterns. The adhesive layer is disposed on the temporary substrate. The light-emitting elements are disposed on the adhesive layer. The adhesive patterns are disposed on the light-emitting elements. A light-emitting element includes a first semiconductor layer, a second semiconductor layer, an active layer disposed between the first semiconductor layer and the second semiconductor layer, and multiple electrodes and an insulating layer respectively electrically connected to the first semiconductor layer and the second semiconductor layer. The insulating layer is disposed on the second semiconductor layer and has multiple contact windows respectively overlapping with the first semiconductor layer and the second semiconductor layer. The electrodes are respectively electrically connected to the first semiconductor layer and the second semiconductor layer through the contact windows of the insulating layer. An adhesive pattern is disposed on the light-emitting element and has a recess, and the recess overlaps with a part of the insulating layer between the electrodes of the light-emitting element.

In an embodiment of the disclosure, one of the light-emitting elements includes a first portion and a second portion. The first portion is disposed in one of the openings of the auxiliary pattern layer. The first portion is located between the second portion and one of the adhesive patterns, and the second portion is disposed outside the one of the openings of the auxiliary pattern layer.

In an embodiment of the disclosure, a side wall of the auxiliary pattern layer defines one of the openings, and a side wall of one of the light-emitting elements is directly in contact with the side wall of the auxiliary pattern layer.

In an embodiment of the disclosure, the auxiliary pattern layer includes multiple vertical portions and multiple horizontal portions. The vertical portions and the horizontal portions are interlaced to define the openings of the auxiliary pattern layer, and the vertical portions and the horizontal portions of the auxiliary pattern layer separate the light-emitting elements.

In an embodiment of the disclosure, the auxiliary pattern layer further includes multiple auxiliary portions respectively disposed in the openings of the auxiliary pattern layer.

In an embodiment of the disclosure, a height of one of the auxiliary portions in a direction perpendicular to the temporary storage substrate is lower than a height of one of the vertical portions and the horizontal portions in the direction perpendicular to the temporary storage substrate.

In an embodiment of the disclosure, one of the auxiliary portions extends between the electrodes of one of the light-emitting elements.

In an embodiment of the disclosure, in a top view of the light-emitting element panel, one of the adhesive patterns and one of the openings of the auxiliary pattern layer substantially coincide.

In an embodiment of the disclosure, in a top view of the light-emitting element panel, one of the light-emitting elements and one of the openings of the auxiliary pattern layer substantially coincide.

### BRIEF DESCRIPTION OF THE DRAWINGS

FIG. 1A to FIG. 1F are schematic cross-sectional views of a manufacturing process of a light-emitting element panel according to a first embodiment of the disclosure.

FIG. 2A to FIG. 2D are schematic cross-sectional views of a manufacturing process of an auxiliary pattern layer and an adhesive pattern according to the first embodiment of the disclosure.

FIG. 3 is a schematic top view of the auxiliary pattern layer according to the first embodiment of the disclosure.

FIG. 4 is a schematic top view of the auxiliary pattern layer and the adhesive pattern according to the first embodiment of the disclosure.

FIG. 5 is a schematic top view of a light-emitting element, the adhesive pattern, and the auxiliary pattern layer according to the first embodiment of the disclosure.

FIG. 6A to FIG. 6F are schematic cross-sectional views of a manufacturing process of a light-emitting element panel according to a second embodiment of the disclosure.

FIG. 7A to FIG. 7D are schematic cross-sectional views of a manufacturing process of an auxiliary pattern layer and an adhesive pattern according to the second embodiment of the disclosure.

FIG. 8 is a schematic top view of the auxiliary pattern layer and the adhesive pattern according to the second embodiment of the disclosure.

FIG. 9A to FIG. 9F are schematic cross-sectional views of a manufacturing process of a light-emitting element panel according to a third embodiment of the disclosure.

FIG. 10 is a schematic top view of a light-emitting element according to the third embodiment of the disclosure.

FIG. 11A to FIG. 11F are schematic cross-sectional views of a manufacturing process of a light-emitting element panel according to a fourth embodiment of the disclosure.

FIG. 12 is a schematic top view of a light-emitting element according to the fourth embodiment of the disclosure.

FIG. 13 shows a first conductive pattern and a second conductive pattern of an electrode of FIG. 12.

### DETAILED DESCRIPTION OF DISCLOSED EMBODIMENTS

Reference will now be made in detail to the exemplary embodiments of the disclosure, examples of the exemplary embodiments are illustrated in the drawings. Wherever possible, the same reference numerals are used in the drawings and the description to refer to the same or similar parts.

It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

As used herein, “about”, “approximately”, or “substantially” includes the stated value and an average value within an acceptable deviation range of the particular value as determined by persons skilled in the art, while taking into account the measurement in discussion and a particular amount of error (that is, the limitation of a measurement system) associated with the measurement. For example, “about” may mean within one or more standard deviations or within ±30%, ±20%, ±15%, ±10%, or ±5% of the stated value. Furthermore, “about”, “approximately”, or “substantially” used herein may choose a more acceptable deviation range or standard deviation according to optical properties, etching properties, or other properties and may not apply one standard deviation to all properties.

Unless otherwise defined, all terms (including technical and scientific terms) used herein have the same meaning as commonly understood by persons skilled in the art to which the disclosure belongs. It should be understood that the terms, such as those defined in commonly used dictionaries, should be interpreted as having meanings consistent with the prior art and the context of the disclosure, and should be interpreted in an idealized or overly formal manner, unless specifically defined herein.

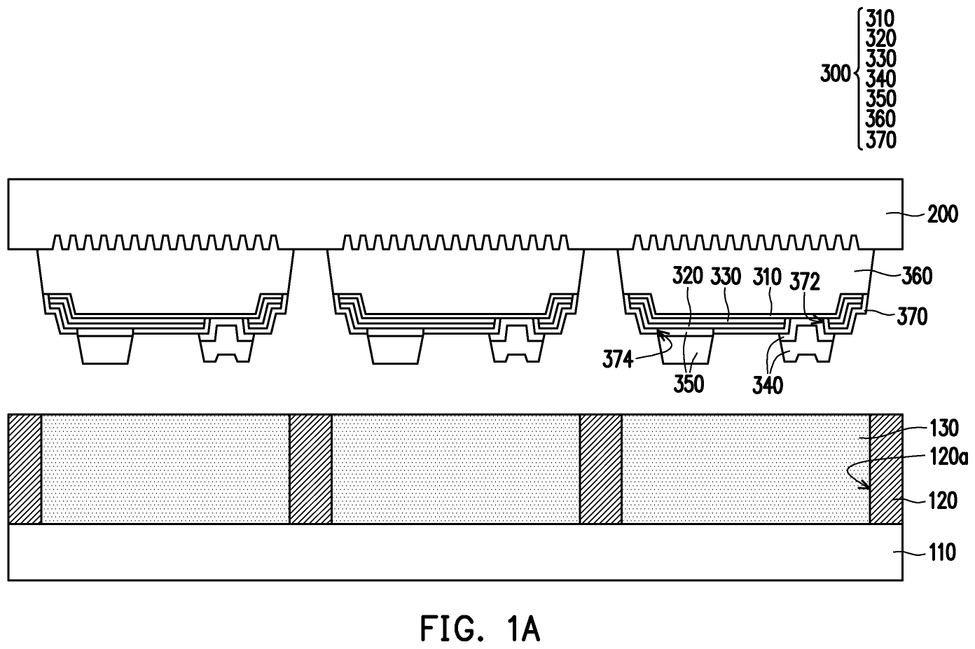

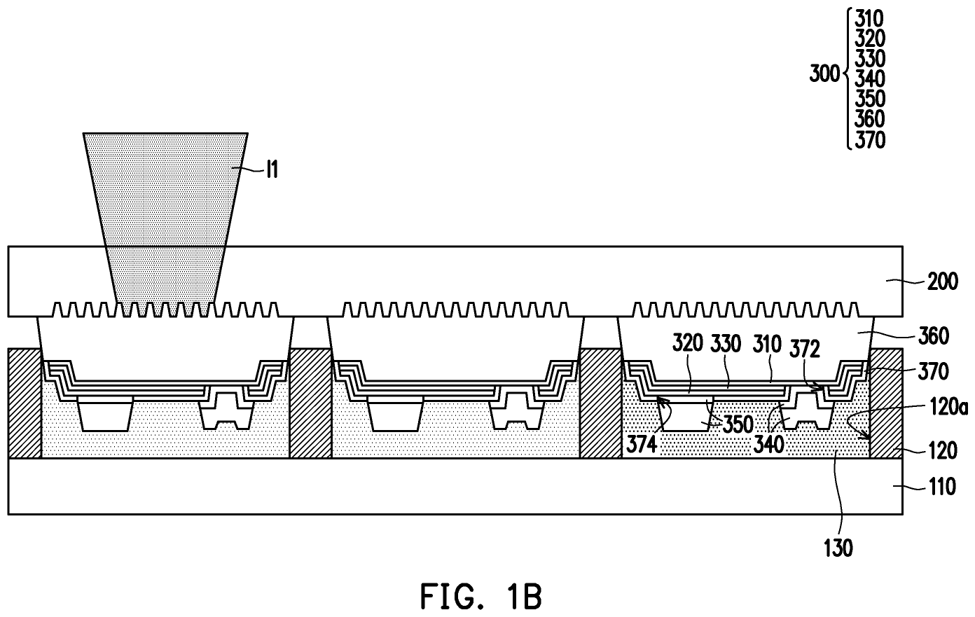

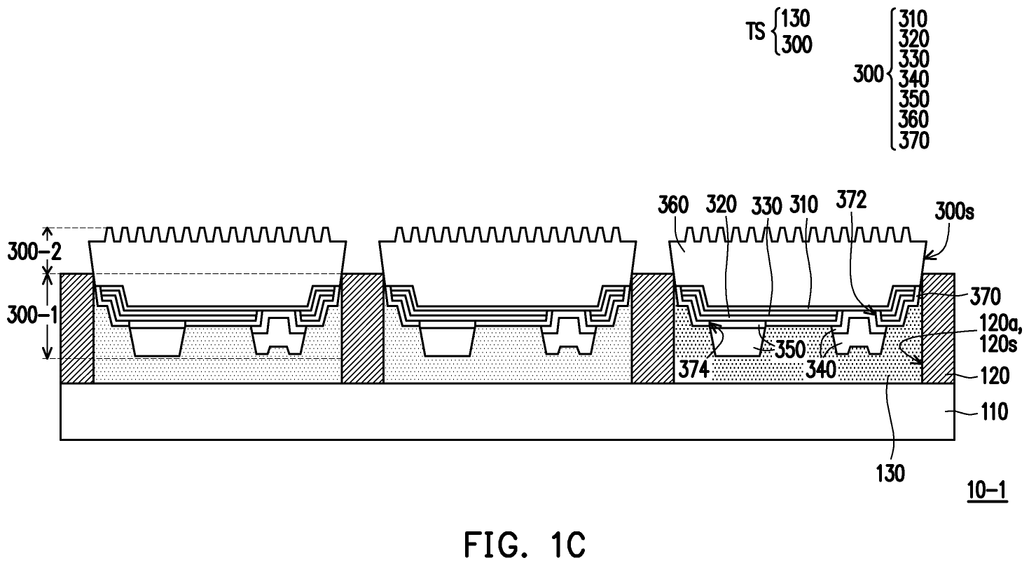

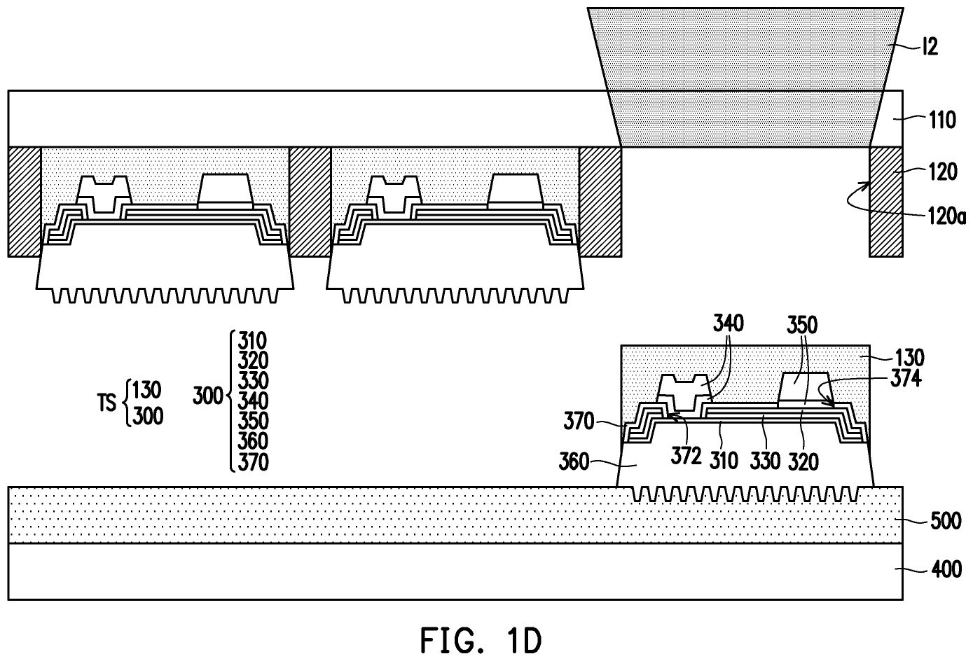

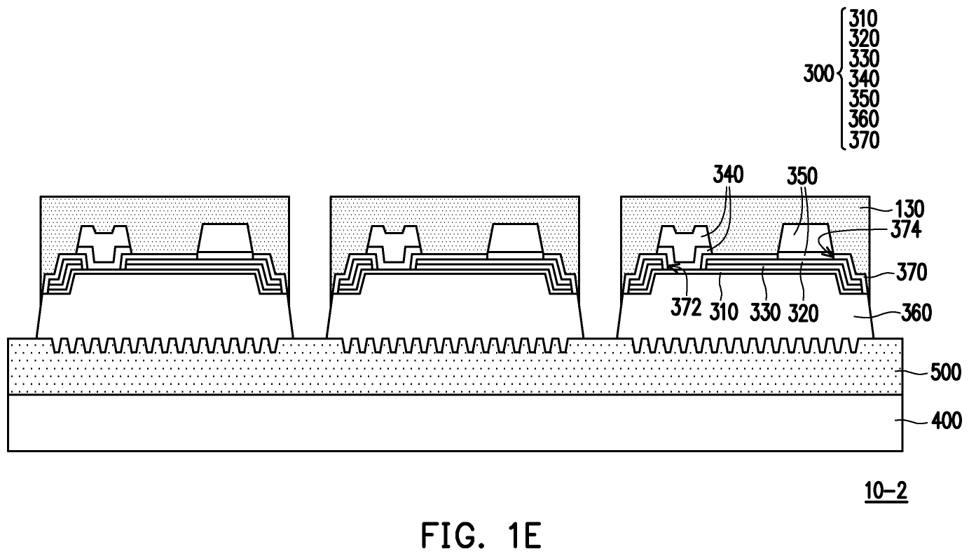

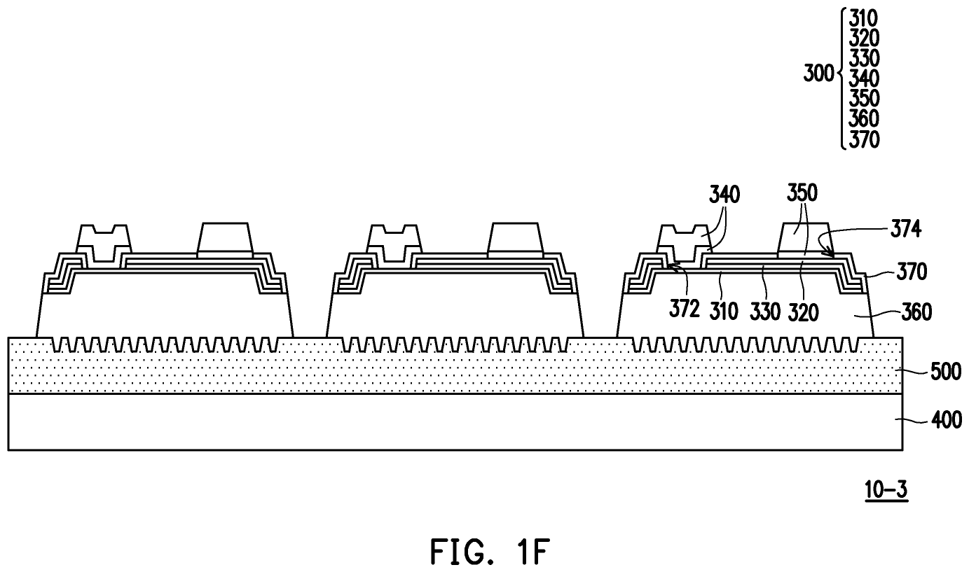

FIG. 1A to FIG. 1F are schematic cross-sectional views of a manufacturing process of a light-emitting element panel according to a first embodiment of the disclosure.

Please refer to FIG. 1A. Firstly, a temporary storage substrate 110 is provided. In the embodiment, the material of the temporary storage substrate 110 is, for example, glass or sapphire. However, the disclosure is not limited thereto, and in other embodiments, the material of the temporary storage substrate 110 may also be other materials.

Next, an auxiliary pattern layer 120 and multiple adhesive patterns 130 are formed on the temporary storage substrate 110. The auxiliary pattern layer 120 is disposed on the temporary storage substrate 110 and has multiple openings 120a. The adhesive patterns 130 are respectively disposed in the openings 120a of the auxiliary pattern layer 120.

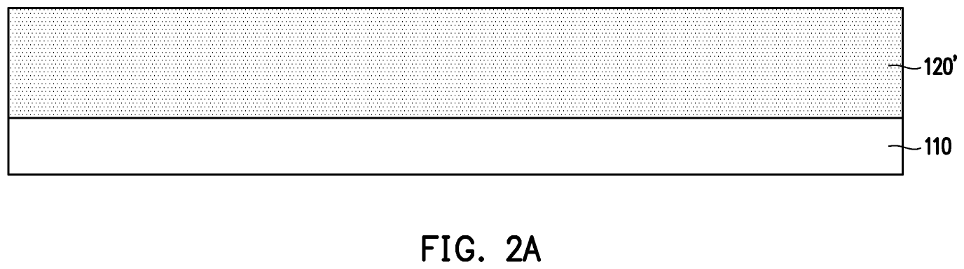

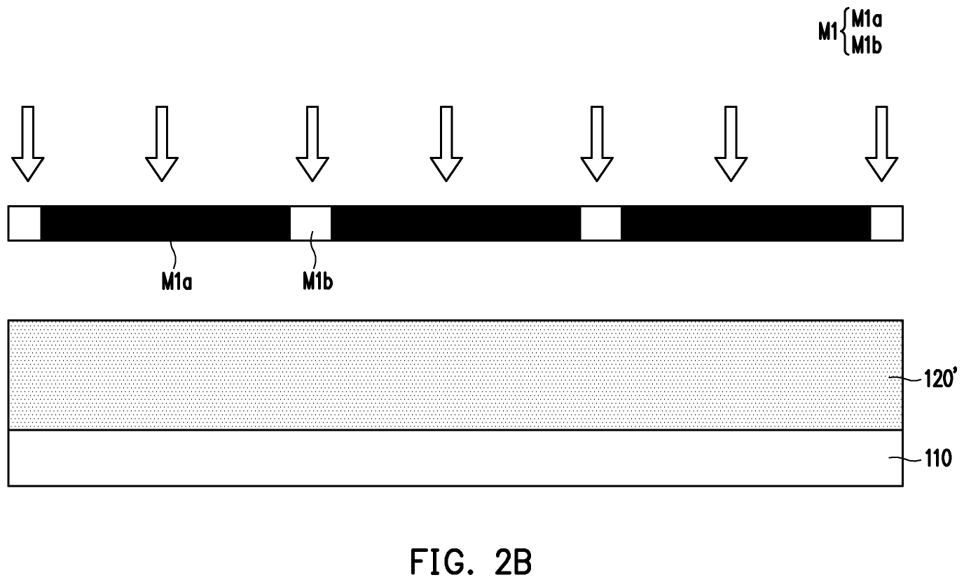

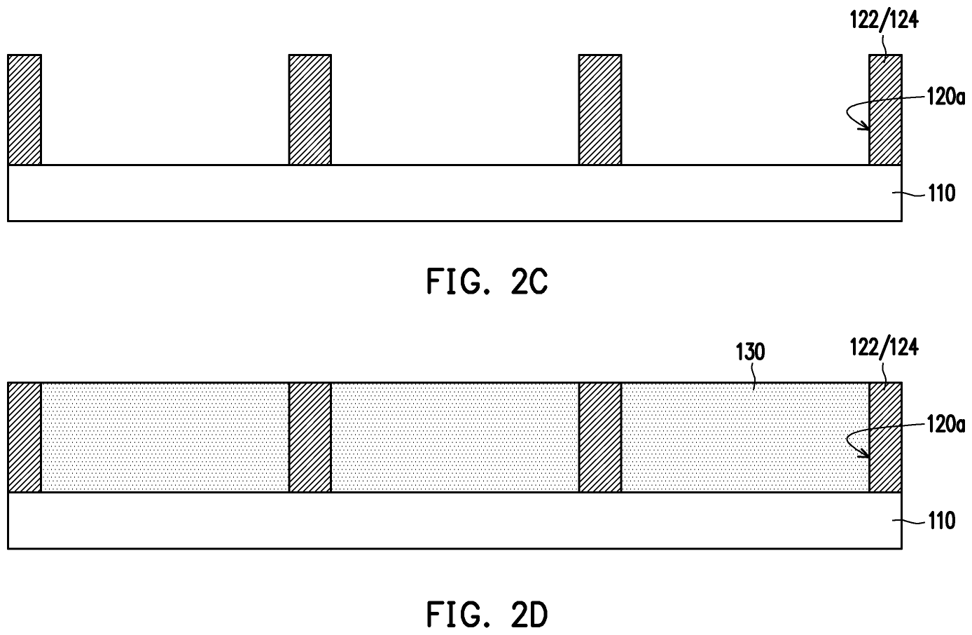

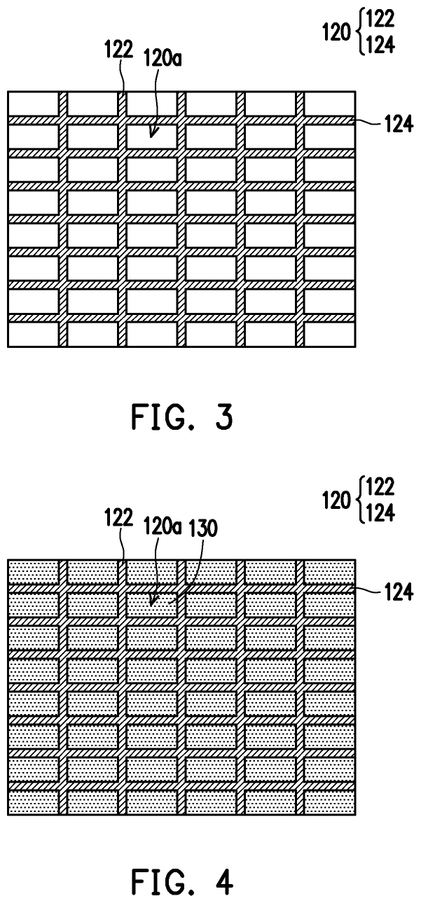

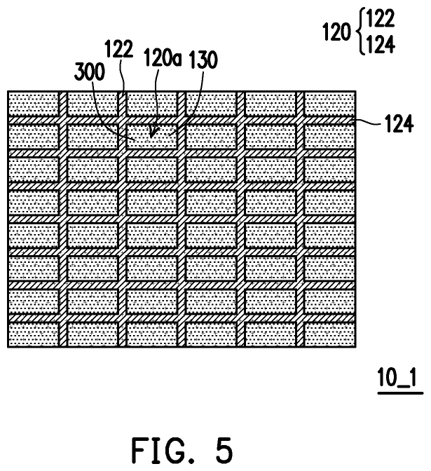

FIG. 2A to FIG. 2D are schematic cross-sectional views of a manufacturing process of an auxiliary pattern layer and an adhesive pattern according to the first embodiment of the disclosure. FIG. 3 is a schematic top view of the auxiliary pattern layer according to the first embodiment of the disclosure. FIG. 4 is a schematic top view of the auxiliary pattern layer and the adhesive pattern according to the first embodiment of the disclosure. The manufacturing process of the auxiliary pattern layer 120 and the adhesive pattern 130 is illustrated below with reference to FIG. 2A to FIG. 2D, FIG. 3, and FIG. 4.

Please refer to FIG. 2A. Firstly, an auxiliary material layer 120′ is formed on the temporary storage substrate 110. Please refer to FIG. 2B and FIG. 2C. Next, the auxiliary material layer 120′ is patterned to form the auxiliary pattern layer 120 having the openings 120a. For example, in the embodiment, the material of the auxiliary material layer 120′ may optionally be a photoresist, and an exposure procedure may be performed on the auxiliary material layer 120′ using a photomask M1. Then, a developing procedure is performed on the exposed auxiliary material layer 120′ to form the auxiliary pattern layer 120. In the embodiment, the material of the auxiliary material layer 120′ may optionally be a positive photoresist. The photomask M1 has a light-shielding area M1a having a light transmittance of substantially 0% and a first light-transmitting area M1b having a light transmittance of substantially 100%. After completing the exposure procedure using the photomask M1 and completing the developing procedure, a part of the auxiliary material layer 120′ corresponding to the light-shielding area M1a of the photomask M1 is removed to form the opening 120a of the auxiliary pattern layer 120, and another part of the auxiliary material layer 120′ corresponding to the first light-transmitting area M1b of the photomask M1 is retained to form the physical auxiliary pattern layer 120. However, the disclosure is not limited thereto, and in other embodiments, the auxiliary pattern layer 120 may also be formed using other manners.

In addition, the disclosure also does not limit that the material used to manufacture the auxiliary pattern layer 120 can only be the positive photoresist, as long as the material used to manufacture the auxiliary pattern layer 120 has no reaction or a low reaction rate to a laser 12 (marked in FIG. 1D). For example, the material with no reaction or a low reaction rate to the laser 12 (marked in FIG. 1D) may be a negative photoresist, a black resin, a metal, or a polymer, but the disclosure is not limited thereto.

Please refer to FIG. 2C and FIG. 3. In the embodiment, the auxiliary pattern layer 120 includes multiple vertical portions 122 and multiple horizontal portions 124, wherein the vertical portions 122 and the horizontal portions 124 are interlaced to define the openings 120a of the auxiliary pattern layer 120. The openings 120a of the auxiliary pattern layer 120 are arranged in an array.

Please refer to FIG. 2D and FIG. 4. Next, the adhesive patterns 130 are respectively formed in the openings 120a of the auxiliary pattern layer 120. Please refer to FIG. 4. In the embodiment, in the top view of the light-emitting element panel, the adhesive pattern 130 and the opening 120a of the auxiliary pattern layer 120 may substantially coincide. Please refer to FIG. 2D. In the embodiment, each adhesive pattern 130 may fill up one corresponding opening 120a of the auxiliary pattern layer 120. In the embodiment, the adhesive pattern 130 may be formed in the opening 120a of the auxiliary pattern layer 120 optionally using an injecting procedure, but the disclosure is not limited thereto.

Please refer to FIG. 1A. Next, a growth substrate 200 and multiple light-emitting elements 300 formed on the growth substrate 200 are provided. Each light-emitting element 300 includes a first semiconductor layer 310, a second semiconductor layer 320, an active layer 330 disposed between the first semiconductor layer 310 and the second semiconductor layer 320, and multiple electrodes 340 and 350 respectively electrically connected to the first semiconductor layer 310 and the second semiconductor layer 320.

In the embodiment, each light-emitting element 300 may also optionally include an epitaxial layer 360. The first semiconductor layer 310 is formed on the epitaxial layer 360, the epitaxial layer 360 is located between the growth substrate 200 and the first semiconductor layer 310, and the first semiconductor layer 310 is located between the epitaxial layer 360 and the active layer 330. For example, in the embodiment, the growth substrate 200 is sapphire, the epitaxial layer 360 is undoped gallium nitride, the first semiconductor layer 310 is n-type gallium nitride, the active layer 330 is a multiple quantum well, and the second semiconductor layer 320 may be p-type gallium nitride, but the disclosure is not limited thereto.

In the embodiment, each light-emitting element 300 may further include an insulating layer 370 disposed on the second semiconductor layer 320 and having multiple contact windows 372 and 374 respectively overlapping with the first semiconductor layer 310 and the second semiconductor layer 320. The electrodes 340 and 350 are respectively electrically connected to the first semiconductor layer 310 and the second semiconductor layer 320 through the contact windows 372 and 374 of the insulating layer 370.

FIG. 5 is a schematic top view of a light-emitting element, the adhesive pattern, and the auxiliary pattern layer according to the first embodiment of the disclosure. The light-emitting element 300, the adhesive pattern 130, and the auxiliary pattern layer 120 of FIG. 5 correspond to the light-emitting element 300, the adhesive pattern 130, and the auxiliary pattern layer 120 of FIG. 1C.

Please refer to FIG. 1A to FIG. 1C and FIG. 5. Next, the light-emitting element 300 is transposed from the growth substrate 200 to the adhesive pattern 130 to form a light-emitting element panel 10-1. In detail, as shown in FIG. 1A and FIG. 1B, the light-emitting elements 300 may be respectively disposed on the adhesive patterns 130, so that the light-emitting elements 300 are respectively connected to the adhesive patterns 130. As shown in FIG. 1B and FIG. 1C, next, the light-emitting elements 300 are separated from the growth substrate 200, and the light-emitting elements 300 remain on the adhesive patterns 130. For example, in the embodiment, the light-emitting elements 300 may be separated from the growth substrate 200 using a laser stripping procedure. A center wavelength of a laser 11 used in the laser stripping procedure is, for example, 266 nm, but the disclosure is not limited thereto.

Please refer to FIG. 1C. In the embodiment, each light-emitting element 300 includes a first portion 300-1 and a second portion 300-2. The first portion 300-1 is disposed in a corresponding opening 120a of the auxiliary pattern layer 120, the first portion 300-1 is located between the second portion 300-2 and the adhesive pattern 130, and the second portion 300-2 is disposed outside the opening 120a of the auxiliary pattern layer 120. In short, in the embodiment, a part of each light-emitting element 300 is buried in the opening 120a of the auxiliary pattern layer 120 and squeezes the adhesive pattern 130 in the opening 120a, and another part of each light-emitting element 300 protrudes outside the auxiliary pattern layer 120 and the adhesive pattern 130.

Please refer to FIG. 1C. In the embodiment, a side wall 120s of the auxiliary pattern layer 120 defines the opening 120a, and a side wall 300s of the light-emitting element 300 is directly in contact with the side wall 120s of the auxiliary pattern layer 120. Please refer to FIG. 1C and FIG. 5. In other words, in the embodiment, a part of each light-emitting element 300 may be embedded into the corresponding opening 120a of the auxiliary pattern layer 120. Please refer to FIG. 5. In the embodiment, the vertical portions 122 and the horizontal portions 124 of the auxiliary pattern layer 120 separate the light-emitting elements 300. Please refer to FIG. 5. In the top view of the light-emitting element panel 10-1, the light-emitting element 300 and the opening 120a of the auxiliary pattern layer 120 substantially coincide, but the disclosure is not limited thereto.

Please refer to FIG. 1D. Next, another temporary storage substrate 400 and an adhesive layer 500 disposed on the temporary storage substrate 400 are provided. In the embodiment, the adhesive layer 500 may completely cover the temporary storage substrate 400, but the disclosure is not limited thereto. Please refer to FIG. 1D and FIG. 1E. Next, the light-emitting element 300 on the temporary storage substrate 110 is transposed to the adhesive layer 500 to form another light-emitting element panel 10-2. The light-emitting element panel 10-2 includes the temporary storage substrate 400, the adhesive layer 500 disposed on the temporary storage substrate 400, the light-emitting element 300 disposed on the adhesive layer 500, and the adhesive pattern 130 disposed on the light-emitting element 300. For example, in the embodiment, the adhesive pattern 130 may be separated from the temporary storage substrate 110 using a laser stripping procedure, so that the light-emitting element 300 connected to the adhesive pattern 130 is transposed to the adhesive layer 500 on another temporary storage substrate 400. In the embodiment, a central wavelength of the laser 12 used in the laser stripping procedure is, for example, 248 nm, but the disclosure is not limited thereto.

Please refer to FIG. 1C, FIG. 1D, and FIG. 1E. It is worth noting that a reaction rate of the auxiliary pattern layer 120 to the laser 12 is lower than a reaction rate of the adhesive pattern 130 to the laser 12. In other words, a dissociation reaction rate of the auxiliary pattern layer 120 caused by the laser 12 at an interface between the auxiliary pattern layer 120 and the temporary storage substrate 110 is lower than a dissociation reaction rate of the adhesive pattern 130 caused by the laser 12 at an interface between the adhesive pattern 130 and the temporary storage substrate 110. Therefore, in the laser stripping procedure using the laser 12, the adhesive pattern 130 and the light-emitting element 300 connected to the adhesive pattern 130 may be separated from the temporary storage substrate 110 and the auxiliary pattern layer 120 under the irradiation of the laser 12, and the auxiliary pattern layer 120 remains on the temporary storage substrate 110.

The light-emitting elements 300 and the adhesive patterns 130 respectively connected to the light-emitting elements 300 are respectively disposed in the openings 120a of the auxiliary pattern layer 120. Each adhesive pattern 130 and the light-emitting element 300 connected thereto form a structure to be transposed TS. As shown in FIG. 1C, before transposing multiple structures to be transposed TS to the adhesive layer 500 on another temporary storage substrate 400, the structures to be transposed TS are separated by the auxiliary pattern layer 120. Therefore, as shown in FIG. 1D, during the process of transposing the structures to be transposed TS to the adhesive layer 500 on another temporary storage substrate 400, the structure to be transposed TS does not stick to the adhesive patterns 130 of other structures to be transposed TS to cause offset and/or rotation. As such, transfer yield of the light-emitting element 300 can be improved.

In addition, since the structures to be transposed TS are separated by the auxiliary pattern layer 120 before being transposed, each structure to be transposed TS does not stick to the adhesive pattern 130 of other structures to be transposed TS. Therefore, the structure to be transposed TS can be separated from the temporary storage substrate 110 and transposed to the adhesive layer 500 without using the high-power laser 12. In a case where the power of the laser 12 is not high, during the transposition process, the probability of the light-emitting element 300 of the structure to be transposed TS being damaged by the laser 12 is greatly reduced.

Please refer to FIG. 1E and FIG. 1F. Next, the adhesive patterns 130 on the light-emitting elements 300 are removed, so that another light-emitting element panel 10-3 may be formed. The electrodes 340 and 350 of the light-emitting elements 300 of the light-emitting element panel 10-2 are exposed and adapted to be bonded to multiple pads of a driving backplane (not shown), thereby forming a display device (not shown).

It must be noted here that the following embodiments continue to use the reference numerals and some content of the foregoing embodiment, wherein the same reference numerals are used to indicate the same or similar elements, and description of the same technical content is omitted. For the description of the omitted part, reference may be made to the foregoing embodiment, and there will be no repetition in the following embodiments.

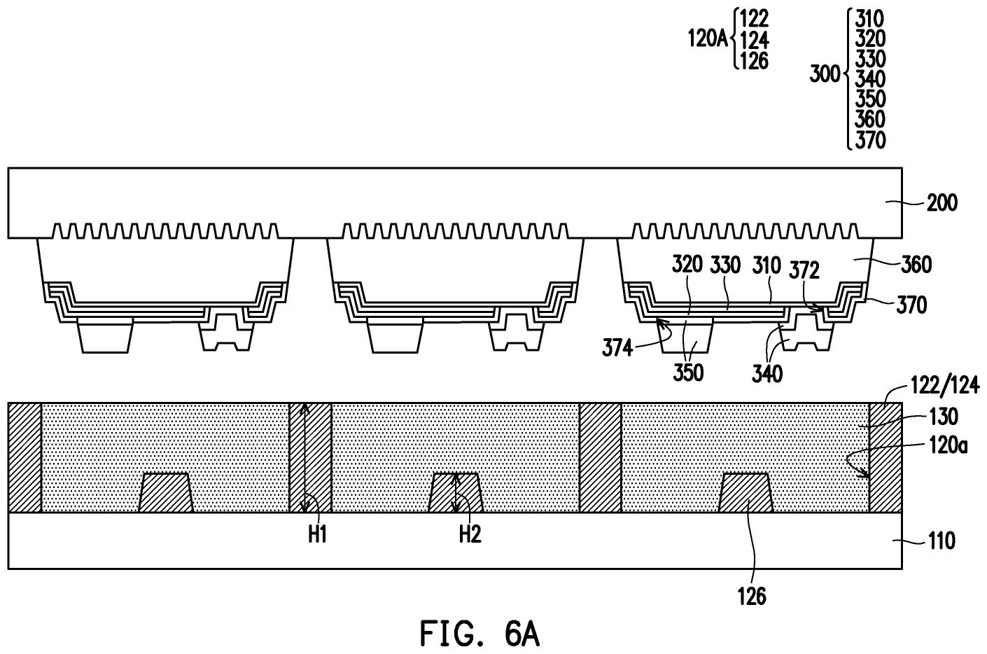

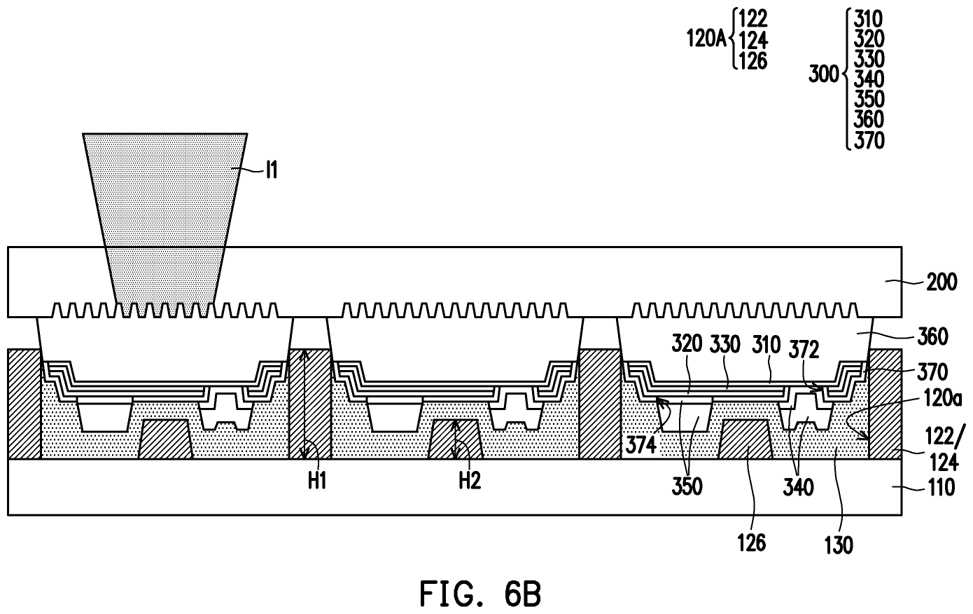

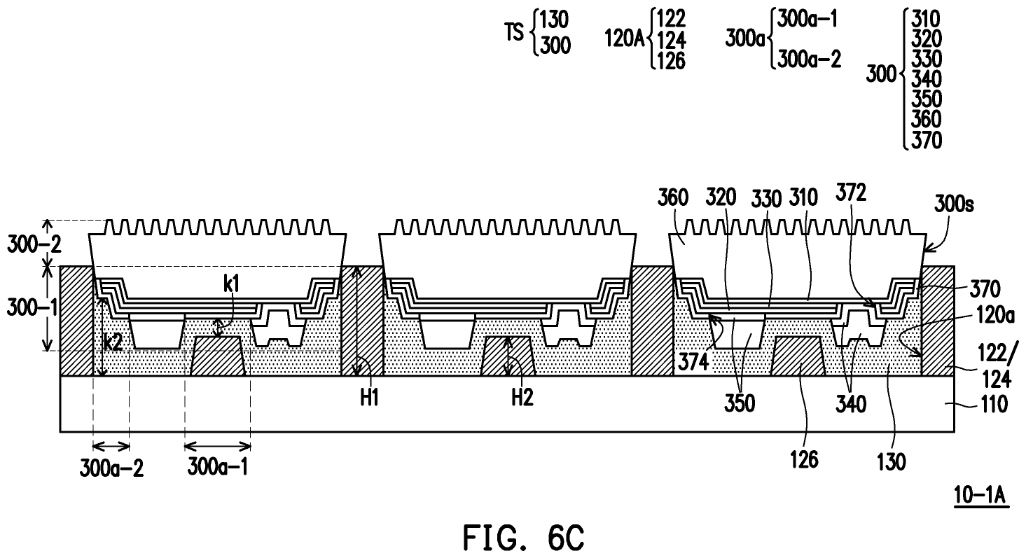

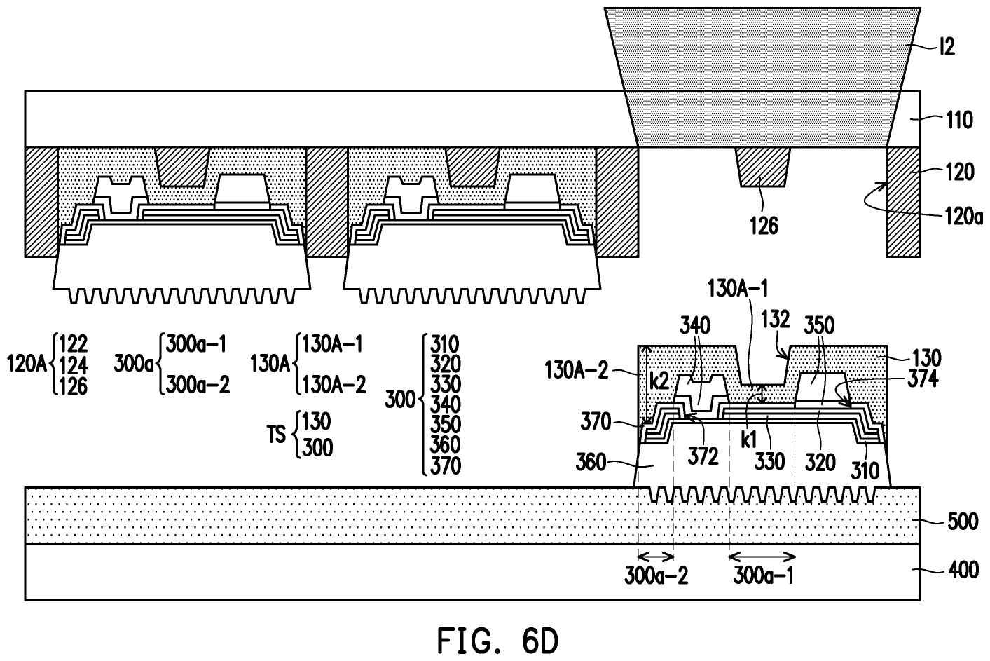

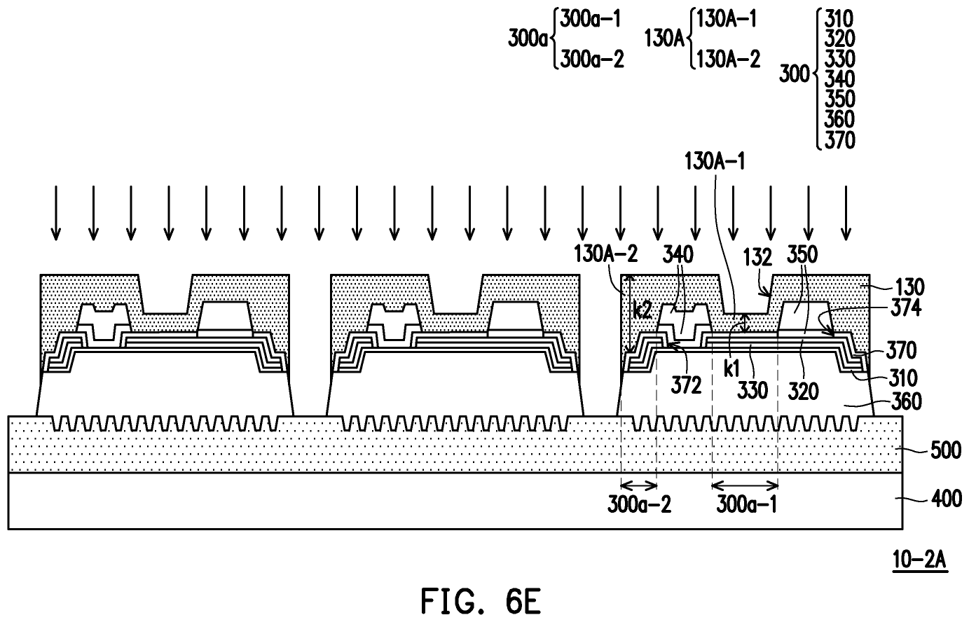

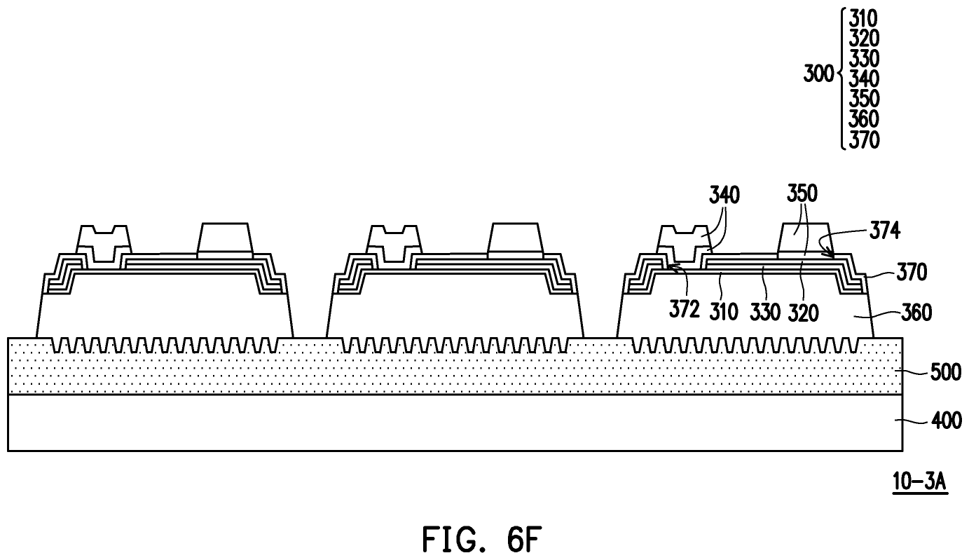

FIG. 6A to FIG. 6F are schematic cross-sectional views of a manufacturing process of a light-emitting element panel according to a second embodiment of the disclosure. The manufacturing process of light-emitting element panels 10-1A, 10-2A, and 10-3A of FIG. 6A to FIG. 6F is similar to the manufacturing process of the light-emitting element panels 10-1, 10-2, and 10-3 of FIG. 1A to FIG. 1F, and the difference between the two is that auxiliary pattern layers 120 and 120A manufactured by the two are different.

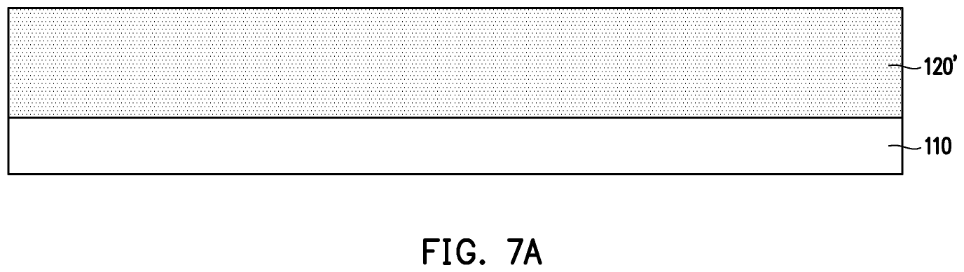

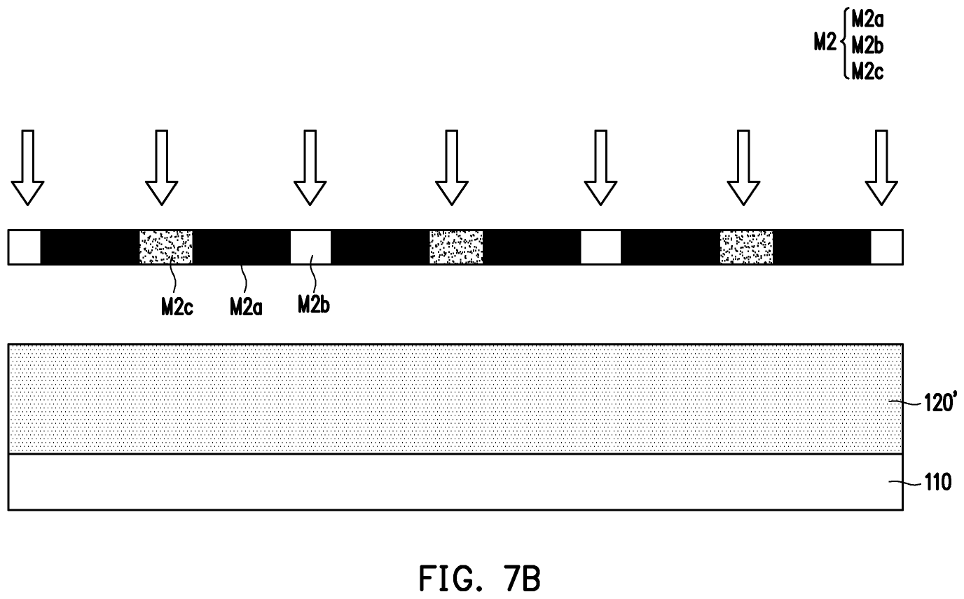

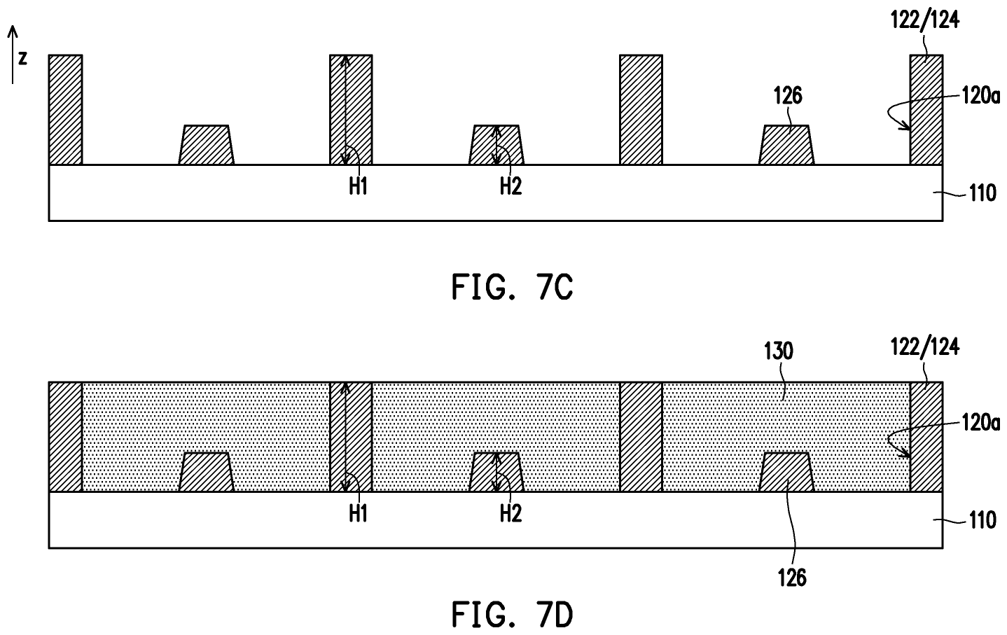

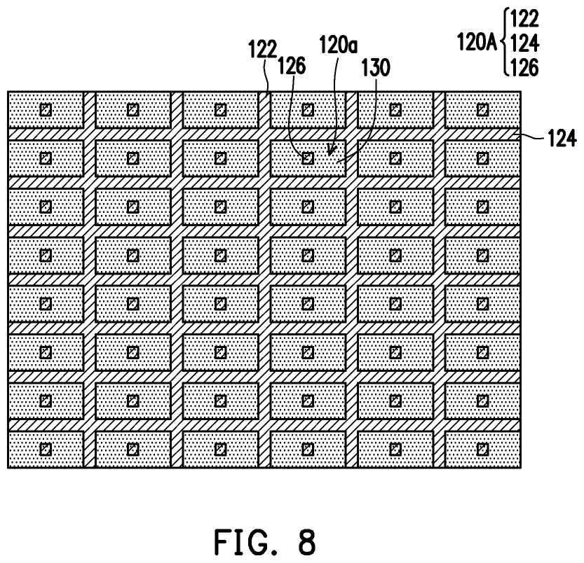

FIG. 7A to FIG. 7D are schematic cross-sectional views of a manufacturing process of an auxiliary pattern layer and an adhesive pattern according to the second embodiment of the disclosure. FIG. 8 is a schematic top view of the auxiliary pattern layer and the adhesive pattern according to the second embodiment of the disclosure. The difference between the structure and the manufacturing process of the auxiliary pattern layer 120A of the embodiment and the auxiliary pattern layer 120 of the first embodiment will be described below. For other sameness or similarities, please refer to the foregoing description, and there will be no repetition here.

Please refer to FIG. 7A to FIG. 7C. In the embodiment, the auxiliary material layer 120′ is also patterned using a photomask M2 to form the auxiliary pattern layer 120A. Different from the first embodiment, the photomask M2 of the embodiment is a grayscale photomask. In detail, the photomask M2 not only has a light-shielding area M2a having a light transmittance of substantially 0% and a first light-transmitting area M2b having a light transmittance of substantially 100%, but also has a second light-transmitting area M2c having a light transmittance of between 0% to 100%. The light transmittance of the second light-transmitting area M2c is, for example, between 20% and 80%, but the disclosure is not limited thereto. Please refer to FIG. 7B, FIG. 7C, and FIG. 8. In the embodiment, the auxiliary pattern layer 120A patterned using the photomask M2 not only has the vertical portion 122 and the horizontal portion 124 corresponding to the first light-transmitting area M2b of the photomask M2 and the opening 120a corresponding to the light-shielding area M2a of the photomask M2, but also has an auxiliary portion 126 corresponding to the second light-transmitting area M2c of the photomask M2. Multiple auxiliary portions 126 are respectively disposed in the openings 120a of the auxiliary pattern layer 120A. A height H2 of the auxiliary portion 126 in a direction z perpendicular to the temporary storage substrate 110 is lower than a height H1 of one of the vertical portion 122 and the horizontal portion 124 in the direction z. For example, in the embodiment, 5 μm≤H1≤10 μm and 1 μm≤H2≤3 μm, but the disclosure is not limited thereto.

Please refer to FIG. 6A to FIG. 6C and FIG. 8. Different from the first embodiment, in the embodiment, when the light-emitting element 300 is transposed from the growth substrate 200 to the adhesive pattern 130 of the temporary storage substrate 110 to form the light-emitting element panel 10-1A, the auxiliary portion 126 of the auxiliary pattern layer 120A extends between the electrodes 340 and 350 of the light-emitting element 300, so that a thickness k1 of a part of the adhesive pattern 130 between the electrodes 340 and 350 of the light-emitting element 300 is thinner. In detail, the light-emitting element 300 has a surface 300a facing the temporary storage substrate 110, the surface 300a includes a first area 300a-1 located between the electrodes 340 and 350 and a second area 300a-2 located outside the electrodes 340 and 350 and the first area 300a-1, and the thickness k1 of the part of the adhesive pattern 130 disposed on the first area 300a-1 of the surface 300a of the light-emitting element 300 is less than a thickness k2 of another part of the adhesive pattern 130 disposed on the second area 300a-2 of the surface 300a of the light-emitting element 300.

Please refer to FIG. 6D and FIG. 6E. An adhesive pattern 130A and the light-emitting element 300 connected to the adhesive pattern 130A are also transposed to the adhesive layer 500 on another temporary storage substrate 400. Please refer to FIG. 6D and FIG. 6E. The adhesive pattern 130A is disposed on the light-emitting element 300, and the difference from the first embodiment is that the adhesive pattern 130 of the embodiment has a recess 132 corresponding to the auxiliary portion 126 of the auxiliary pattern layer 120A, and the recess 132 overlaps with a part of the insulating layer 370 between the electrodes 340 and 350 of the light-emitting element 300. The light-emitting element 300 has the surface 300a facing away from the temporary storage substrate 400, the surface 300a has the first area 300a-1 located between the electrodes 340 and 350 and the second area 300a-2 located outside the electrodes 340 and 350 and the first area 300a-1, a part 130A-1 of the adhesive pattern 130A is disposed on the first area 300a-1 of the surface 300a of the light-emitting element 300 and overlaps with the recess 132, another part 130A-2 of the adhesive pattern 130A is disposed on the second area 300a-2 of the surface 300a of the light-emitting element 300, and the thickness k1 of the part 130A-1 of the adhesive pattern 130A is less than the thickness k2 of another part 130A-2 of the adhesive pattern 130A.

Please refer to FIG. 6D to FIG. 6F. It is worth mentioning that through the configuration of the auxiliary portion 126 of the auxiliary pattern layer 120A, the thickness k1 of the part 130A-1 of the adhesive pattern 130A disposed between the electrodes 340 and 350 of the light-emitting element 300 may be thinner, so that when the adhesive pattern 130 on the light-emitting element 300 is removed to form the light-emitting element panel 10-2A, the adhesive pattern 130 is not easy to remain between the electrodes 340 and 350. In this way, the bonding yield between the light-emitting element 300 of the light-emitting element panel 10-3A and the driving backplane (not shown) can be improved.

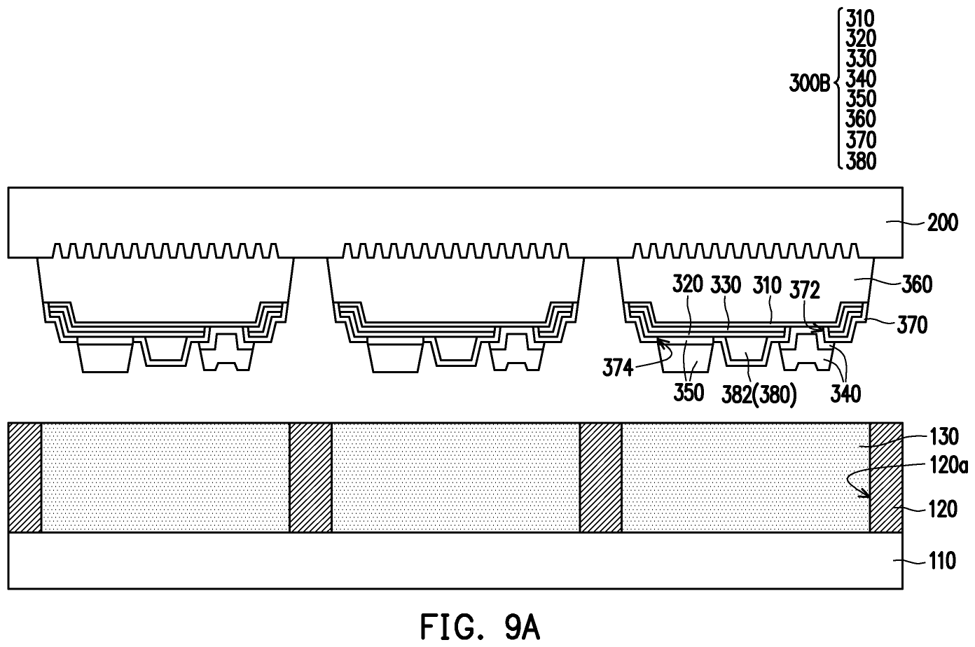

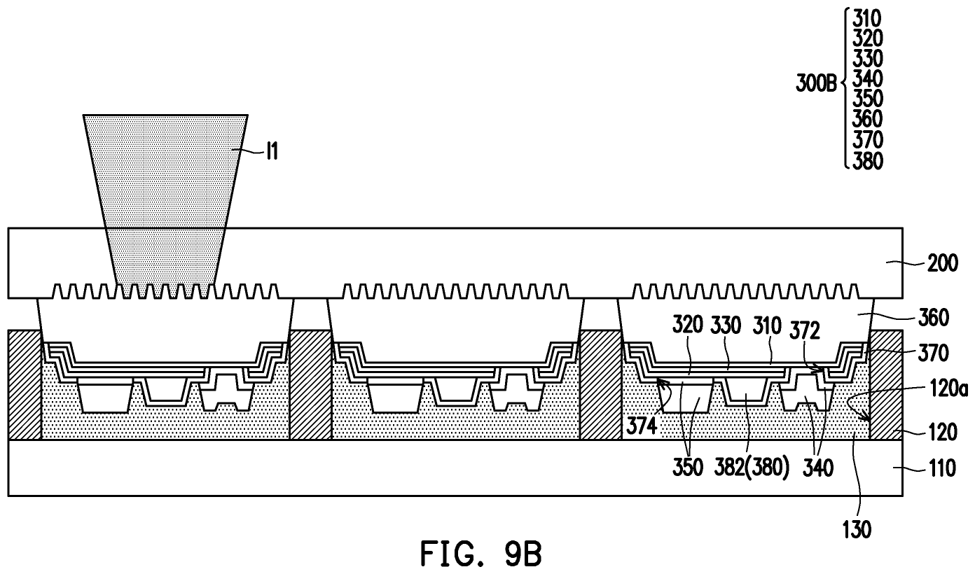

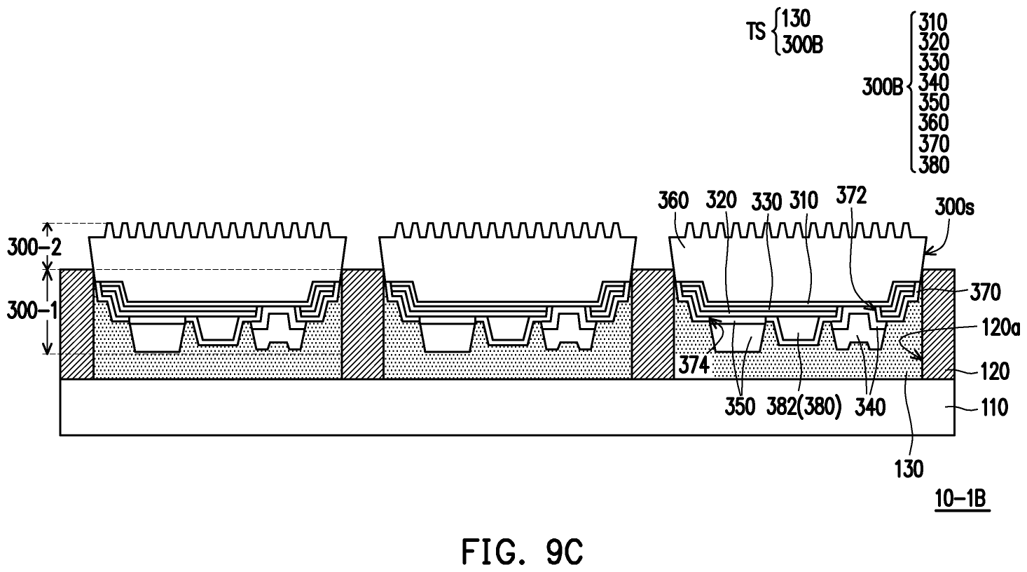

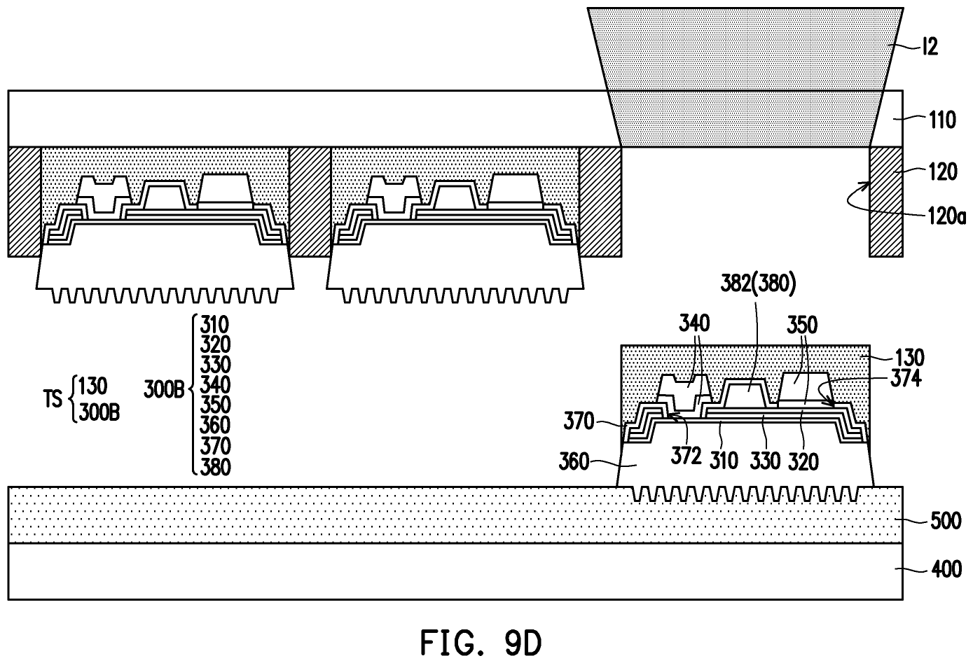

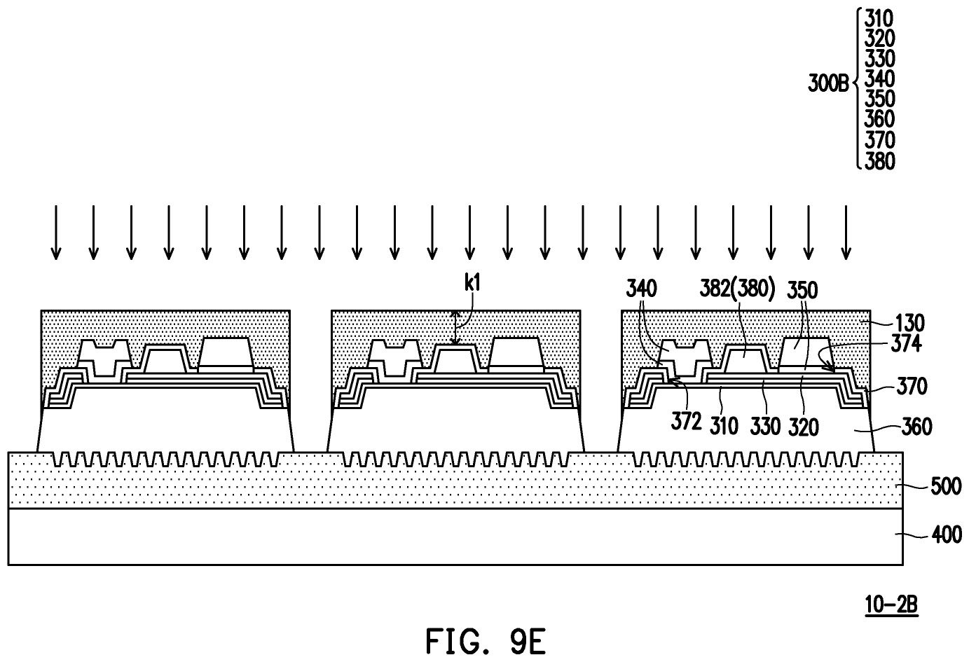

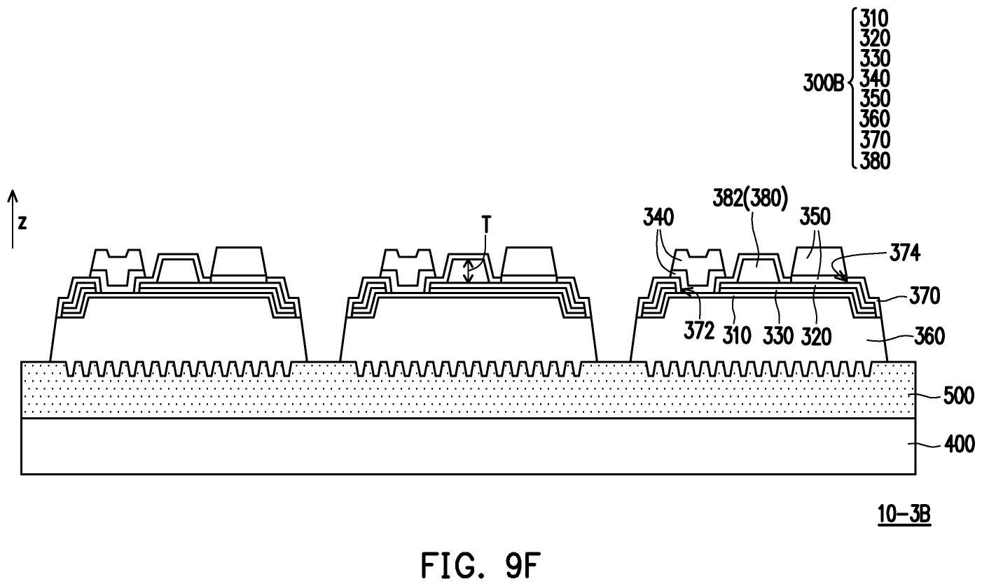

FIG. 9A to FIG. 9F are schematic cross-sectional views of a manufacturing process of a light-emitting element panel according to a third embodiment of the disclosure. The manufacturing process of light-emitting element panels 10-1B, 10-2B, and 10-3B of FIG. 9A to FIG. 9F is similar to the manufacturing process of the light-emitting element panels 10-1 and 10-2 of FIG. 1A to FIG. 1F. The difference between the two is that light-emitting elements 300 and 300B of the two are different. The difference between the light-emitting element 300B of the embodiment and the light-emitting element 300 of the first embodiment are described below. For other sameness or similarities, please refer to the foregoing description.

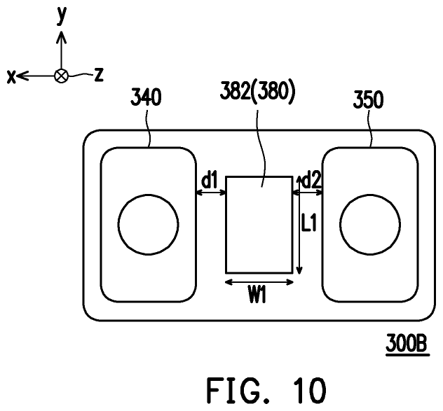

FIG. 10 is a schematic top view of a light-emitting element according to the third embodiment of the disclosure. Please refer to FIG. 9A and FIG. 10, different from the first embodiment, the light-emitting element 300A of the embodiment further includes an electrode 380 disposed on the second semiconductor layer 320 and located between the electrodes 340 and 350. The insulating layer 370 may cover the electrode 380. Please refer to FIG. 9E. The configuration of the electrode 380 enables the thickness k1 of a part of the adhesive pattern 130 located between the electrodes 340 and 350 to be thinner. Please refer to FIG. 9E and FIG. 9F. As such, when the adhesive pattern 130 on the light-emitting element 300B is removed to form the light-emitting element panel 10-3B, the adhesive pattern 130 is not easy to remain between the electrodes 340 and 350. In this way, the bonding yield between the light-emitting element 300 of the light-emitting element panel 10-3B and the driving backplane (not shown) can be improved.

Please refer to FIG. 9F. For example, in the embodiment, the material of the electrode 380 of the light-emitting element 300 may be selected from gold, silver, aluminum, titanμm, nickel, chromμm, an alloy thereof, or other conductive materials. In the embodiment, a thickness of the electrode 380 of the light-emitting element 300 in the direction z is T, and 0.5 μm ≤T≤1 μm, but the disclosure is not limited thereto. In the embodiment, the electrode 380 of the light-emitting element 300 may optionally include a single first conductive pattern 382, but the disclosure is not limited thereto.

Please refer to FIG. 10, a direction x and a direction y are perpendicular to the direction z and intersect each other, the first conductive pattern 382 of the electrode 380 has a width W1 in the direction x, and the first conductive pattern 382 of the electrode 380 has a width L1 in the direction y. In the embodiment, W1≥2 μm and L1≥2 μm, but the disclosure is not limited thereto. There is a distance d1 between the first conductive pattern 382 of the electrode 380 and the electrode 340 in the direction x, and there is a distance d2 between the first conductive pattern 382 of the electrode 380 and the electrode 350 in the direction x. In the embodiment, d1≥2 μm and d2≥2 μm, but the disclosure is not limited thereto.

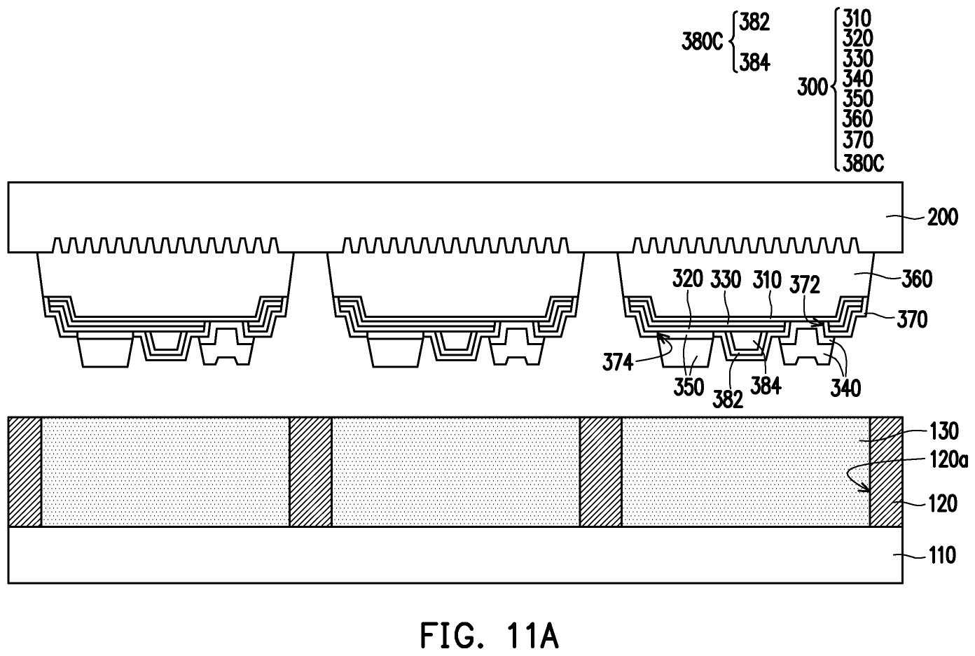

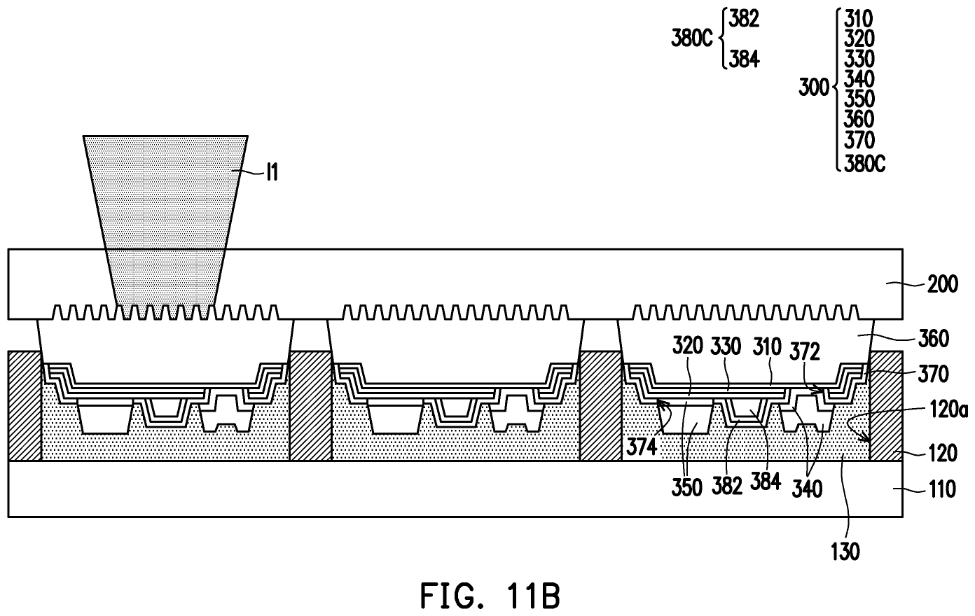

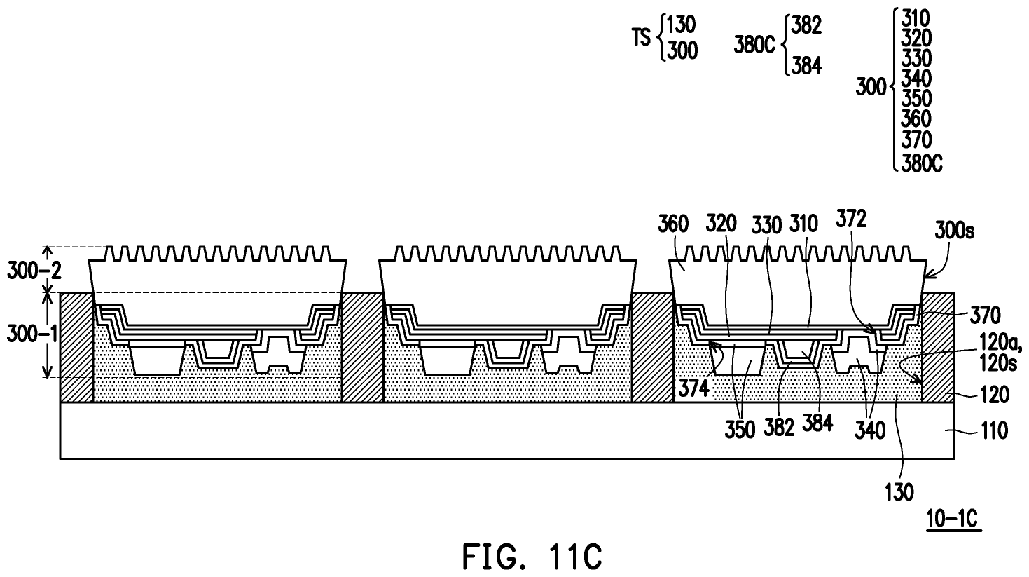

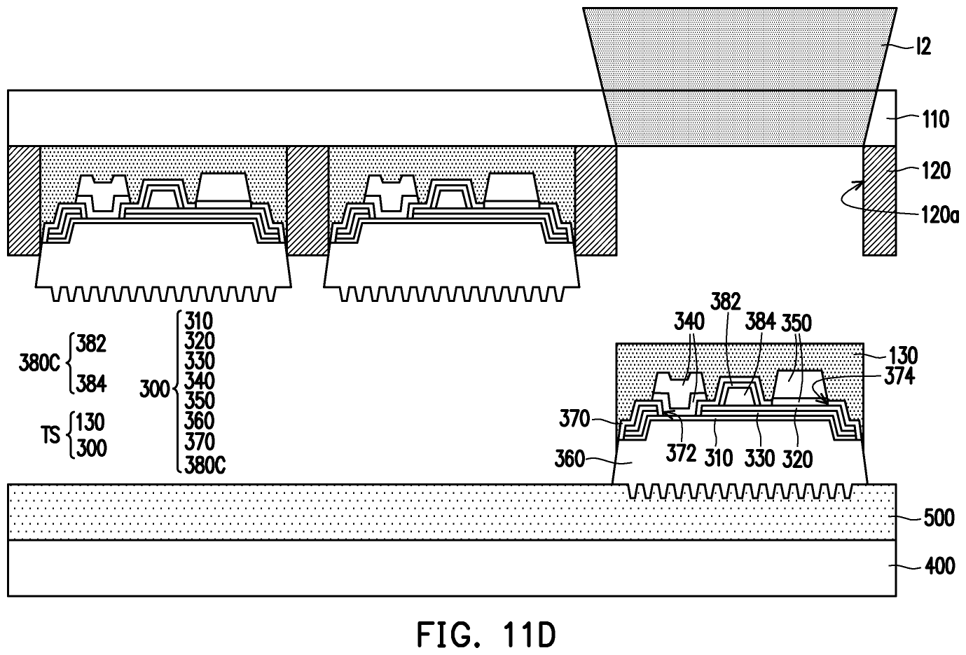

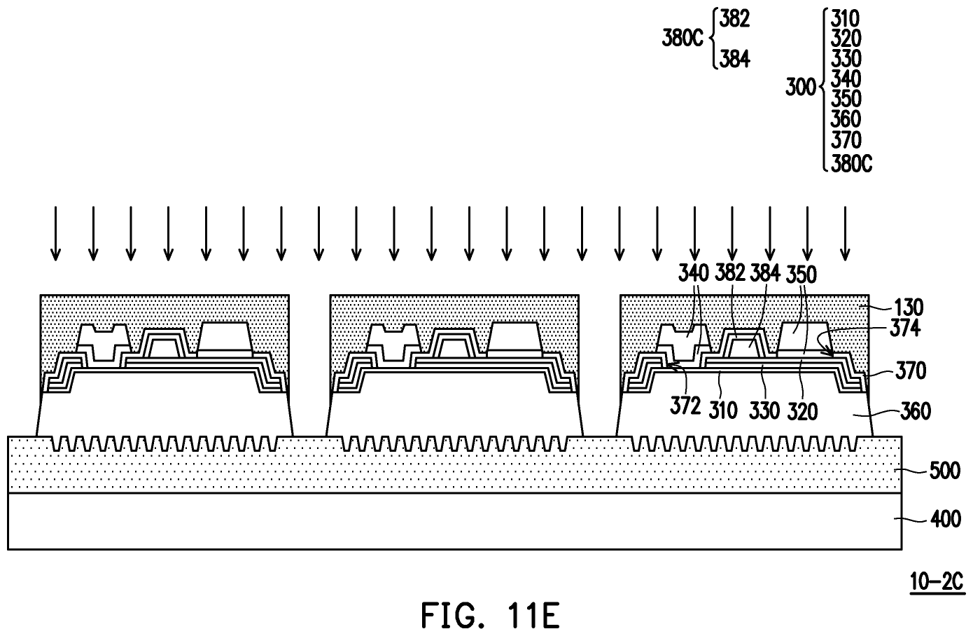

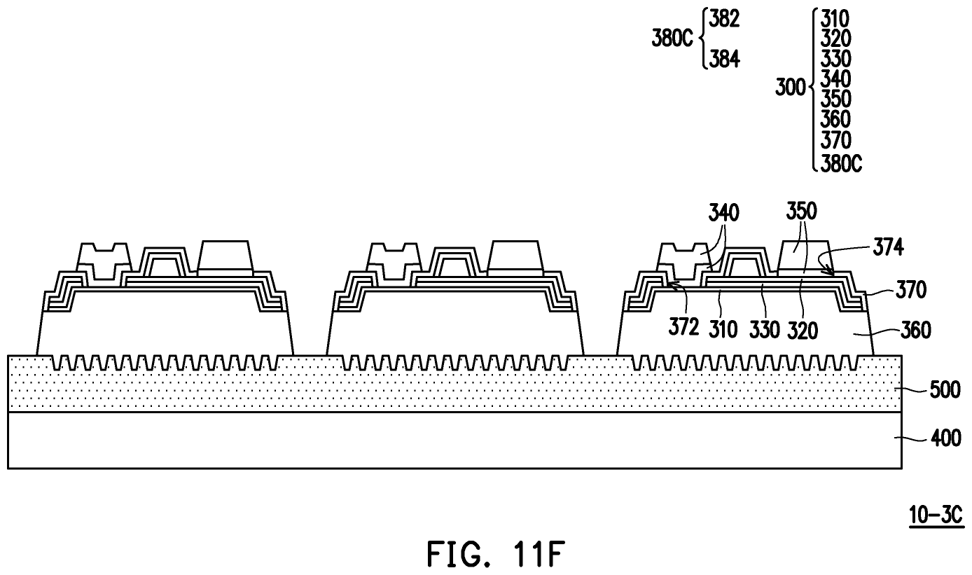

FIG. 11A to FIG. 11F are schematic cross-sectional views of a manufacturing process of a light-emitting element panel according to a fourth embodiment of the disclosure. The manufacturing process of light-emitting element panels 10-1C, 10-2C, and 10-3C of FIG. 11A to FIG. 11F is similar to the manufacturing process of the light-emitting element panels 10-1B, 10-2B, and 10-3B of FIG. 9A to FIG. 9F. The difference between the two is that light-emitting elements 300B and 300C of the two are different. The difference between the light-emitting element 300C of the embodiment and the light-emitting element 300B of the third embodiment are described below. For other sameness or similarities, please refer to the foregoing description.

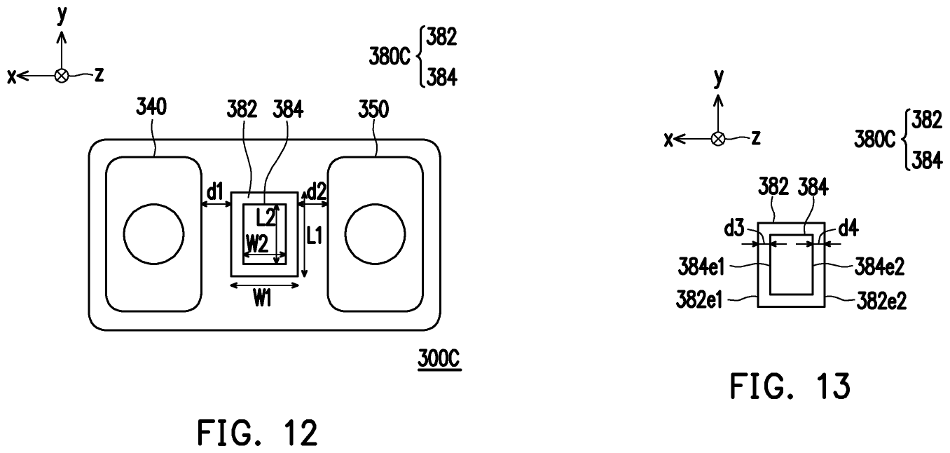

FIG. 12 is a schematic top view of a light-emitting element according to the fourth embodiment of the disclosure. Please refer to FIG. 11A to FIG. 11F and FIG. 12. Different from the third embodiment, an electrode 380C of the light-emitting element 300C of the embodiment may include the first conductive pattern 382 disposed on the second semiconductor layer 320 and a second conductive pattern 384 disposed between the first conductive pattern 382 and the second semiconductor layer 320.

Please refer to FIG. 11C, FIG. 11F, and FIG. 12. In the embodiment, the second conductive pattern 384 of the electrode 380C is disposed within the first conductive pattern 382 of the electrode 380. The first conductive pattern 382 of the electrode 380C has the width W1 in the direction x. The first conductive pattern 382 of the electrode 380C has the width L1 in the direction y. The second conductive pattern 384 of the electrode 380C has a width W2 in the direction x. The second conductive pattern 384 of the electrode 380C has a width L2 in the direction y. In the embodiment, W2≥2 μm, L2≥2 μm, W1≥6 μm, and L1≥6 μm, but the disclosure is not limited thereto.

FIG. 13 shows a first conductive pattern and a second conductive pattern of an electrode of FIG. 12. Please refer to FIG. 13. The first conductive pattern 382 of the electrode 380C has two opposite edges 382e1 and 381e2 arranged in the direction x, the second conductive pattern 384 of the electrode 380 has two opposite edges 384e1 and 384e2 arranged in the direction x, there is a distance d3 between the edge 382e1 of the first conductive pattern 382 of the electrode 380 and the edge 384e1 of the second conductive pattern 384 of the electrode 380 in the direction x, and there is a distance d4 between the edge 382e2 of the first conductive pattern 382 of the electrode 380 and the edge 384e2 of the second conductive pattern 384 of the electrode 380 in the direction x. In the embodiment, d3≥2 μm and d4≥2 μm, but the disclosure is not limited thereto.

What is claimed is:

1. A light-emitting element panel, comprising:
a temporary storage substrate;
an auxiliary pattern layer, disposed on the temporary storage substrate and having a plurality of openings;
a plurality of adhesive patterns, respectively disposed in the openings of the auxiliary pattern layer; and
a plurality of light-emitting elements, respectively disposed on the adhesive patterns;
wherein a reaction rate of the auxiliary pattern layer to a laser is lower than a reaction rate of the adhesive patterns to the laser.

2. The light-emitting element panel according to claim 1, wherein one of the light-emitting elements comprises:
a first portion, disposed in one of the openings of the auxiliary pattern layer; and
a second portion, wherein the first portion is located between the second portion and one of the adhesive patterns, and the second portion is disposed outside the one of the openings of the auxiliary pattern layer.

3. The light-emitting element panel according to claim 1, wherein a side wall of the auxiliary pattern layer defines one of the openings, and a side wall of one of the light-emitting elements is directly in contact with the side wall of the auxiliary pattern layer.

4. The light-emitting element panel according to claim 1, wherein the auxiliary pattern layer comprises:
a plurality of vertical portions; and
a plurality of horizontal portions, wherein the vertical portions and the horizontal portions are interlaced to define the openings of the auxiliary pattern layer, and the vertical portions and the horizontal portions of the auxiliary pattern layer separate the light-emitting elements.

5. The light-emitting element panel according to claim 4, wherein the auxiliary pattern layer further comprises:
a plurality of auxiliary portions, respectively disposed in the openings of the auxiliary pattern layer.

6. The light-emitting element panel according to claim 5, wherein a height of one of the auxiliary portions in a direction perpendicular to the temporary storage substrate is lower than a height of one of the vertical portions and the horizontal portions in the direction.

7. The light-emitting element panel according to claim 5, wherein one of the auxiliary portions extends between a plurality of electrodes of one of the light-emitting elements.

8. The light-emitting element panel according to claim 1, wherein in a top view of the light-emitting element panel, one of the adhesive patterns and one of the openings of the auxiliary pattern layer substantially coincide.

9. The light-emitting element panel according to claim 1, wherein in a top view of the light-emitting element panel, one of the light-emitting elements and one of the openings of the auxiliary pattern layer substantially coincide.

10. A light-emitting element panel, comprising:
a temporary storage substrate;
an adhesive layer, disposed on the temporary substrate; and
a plurality of light-emitting elements, disposed on the adhesive layer; and
a plurality of adhesive patterns, disposed on the light-emitting elements;
wherein one of the adhesive patterns is disposed on one of the light-emitting elements, the one of the light-emitting elements comprises a first semiconductor layer, a second semiconductor layer, an active layer disposed between the first semiconductor layer and the second semiconductor layer, and a plurality of electrodes and an insulating layer respectively electrically connected to the first semiconductor layer and the second semiconductor layer, the insulating layer is disposed on the second semiconductor layer and has a plurality of contact windows respectively overlapping with the first semiconductor layer and the second semiconductor layer, the electrodes are respectively electrically connected to the first semiconductor layer and the second semiconductor layer through the contact windows of the insulating layer, the one of the adhesive patterns has a recess, and the recess overlaps with a part of the insulating layer between the electrodes of the light-emitting elements.
